(19) United States
(12) Patent Application Publication
(10) Pub. No.: US 2019/0240565 A1
(43) Pub. Date: Aug. 8, 2019

(54) Osculation Analyzer

(71) Applicant: Stu Rasmussen, Silverton, OR (US)

(72) Inventor: Stu Rasmussen, Silverton, OR (US)

(21) Appl. No.: 16/238,146

(22) Filed: Jan. 2, 2019

Related U.S. Application Data
(60) Provisional application No. 62/709,131, filed on Jan. 4, 2018.

(51) Int. Cl. A63F 13/212; G01R 33/02; A63F 13/214

(52) U.S. Cl. CPC A63F 13/212; A63F 2300/1012; A63F 13/214; G01R 33/02

(57) ABSTRACT

Evaluating interpersonal relationships is a complex subject not easily reduced to quantifiable values. This invention provides one data point for relationship measurement by evaluating the quality and duration of osculatory activity (kissing) of the test subjects. A source of electrical current is supplied and passed through a circuit in which the test subjects, while engaged in kissing related activity, are series elements. It is easily developed from Ohm's and Kirchoff's Laws that the better the interpersonal physical connection (lips, tongue, teeth, flesh etc.), the lower the electrical resistance of the series circuit and the more electrical current will flow. The resultant current flow is measured and mathematically integrated over a period of time to give a relative indication of the intensity and duration of the osculatory activity (kissing) and from that measurement an evaluation of one limited data point regarding the status of the participants interpersonal relationship may be extrapolated. Under certain circumstances the pulse rates of the test subjects may be time-coincidental and this synchronicity may be an additive factor to the osculatory evaluation. The measurement may then be displayed or otherwise presented to the participants. This osculatory measurement apparatus, with the addition of a coin-, token-, currency- or credit-operated triggering device to initiate a measurement will be a unique and useful revenue enhancement tool for restaurants, taverns, coffee shops and other places of assembly. Interconnecting two or more of the osculation evaluation devices and providing a means of comparing the resulting measurements turns osculatory prowess into a competitive game of skill and such competitions can provide further revenue enhancement to establishments hosting the devices.

### CROSS REFERENCE TO RELATED APPLICATIONS

This application is entitled to the benefit of Provisional Patent Application Ser. No. 62/709,131 filed 2018 Jan. 4.

### BACKGROUND

### Field of the Invention

This invention relates generally to novelty amusement apparatus.

### Description of Prior Art

Osculation (Kissing) as a recreational activity has enjoyed wide popularity in most Western cultures and the quality of a kiss is often considered an indicator of the emotional state of the interpersonal relationship between two people. Most of these evaluations are made on a subjective basis by the participants. Objective data is often challenging to obtain due to the difficulty in acquiring measurement data and providing meaningful interpretation thereof.

There have been a number of devices over the years purporting to measure osculatory (kissing) parameters. One of the earliest devices circa 1940 was a coin-operated machine named the “Kiss-O-Meter” which was actually a muscular strength testing machine that based its measurements and indications on the squeezing or gripping force of the operator's hand. There is a description of this device at <http://www.collectorsweekly.com/stories/45315-1945-kiss-o-meter-arcade-fortune-teller> which describes the machine's operation as “The player deposited his coin in the slot and pushed in the coin chute, which set the mechanism. He then squeezed the handle that sat centered on the front of the machine.”. Although mis-named as a variety of kiss tester, this device in operation had nothing whatever to do with kissing.

The electrical conductivity characteristics of human skin and the neuro-electrical characteristics of nerve impulses and muscular stimulation impulses are relatively well known and the core technology of many devices for measuring and evaluating physiological characteristics of biological specimens. Medical technology gives us the EEG, EKG and a plethora of other measurements of biological electrical activity—but these measurements are confined to a single biological entity rather than measuring interpersonal activity between two or more test subjects, although full-motion X-Ray radiographs of kissing activity have been an occasional novelty item.

Electrical experimenters have long known that skin is conductive to some degree and demonstrated this to their personal satisfaction by holding the test leads of an Ohmmeter in one or both hands and viewing the meter indication. No doubt some brave souls using that technology also attempted measurements of the galvanic connectivity between two individuals during a kiss. These measurements would have indicated only the instantaneous transitory value of the connection between test subjects.

An early implementation of a device to evaluate a couple's kissing skill was documented in the September 1948 issue of Radio Craft magazine published and edited by the legendary Hugo Gernsback. The device described in the magazine article was essentially an AC Impedance Bridge with a visual indicator. The test subjects connected themselves to the apparatus by each holding an electrode connected to the device and then engaging in a kiss. From an analysis of the circuit it is apparent that the measurement was subject to a great deal of outside influence such as electromagnetic transients and 60- and 120-Hz power-line induced hum elements. This device also indicated only the instantaneous value of the electro-dermal connectivity between subjects rather than producing a time domain weighted indication, shortcomings which are overcome by my invention.

There was also a coin-operated device referred to as a ‘Kissmeter’ in the late 1970's-early 1980's which, although referring to itself as some sort of kissing measurement was actually only a gross measurement of the skin conductivity of one person who placed a fingertip on electrical contacts on the machine. Grand Master Yoda would instruct us that “One person does not an osculatory encounter comprise.”

U.S. Pat. No. 8,439,755 issued to Hye Yeon Nam of Atlanta, Ga. describes a “game controller using kiss” in which “a game controller includes a magnetic field generation unit to be attached to a tongue of a first user, and a control signal output device to be provided outside a mouth of a second user for outputting a game control signal according to a position of the magnetic field generation unit in the mouth when the tongue of the first user to which the magnetic field generation unit is attached is inserted into the mouth of the second user, wherein the control signal output device measures a magnetic field intensity of the magnetic field generation unit, calculates the position of the magnetic field generation unit in the mouth according to magnetic field intensities measured by the magnetic field sensors, generates a game control signal according to the calculated position, and transmits the generated game control signal to the game apparatus.”. Although this invention may indeed quantify tongue motion and positioning during the act of “French Kissing” it does not address the electrical connectivity which is the essence of a well-executed kiss, ignores the fact that many otherwise perfectly satisfactory kisses do not progress to the “insert tongue and move it around” stage and the inventor's stated requirement of “a magnetic field generation unit to be attached to a tongue of a first user” would seem rather off-putting to a potential user of the device.

### SUMMARY

A device to acquire physio-electric osculatory parameters of one or more test subjects engaged in kissing or other inter-personal physical connections such as holding hands, et cetera, then process and evaluate these measured parameters to provide quantifiable data as to the quality, quantity and duration of the measured personal kissing or other interaction and then finally display or otherwise communicate the result of these measurements and calculations for scientific or entertainment purposes.

### OBJECTS AND ADVANTAGES

The objects of my invention are to provide an easy, quick and intuitive means of measuring and evaluating the kissing skill of human biological subjects and providing quantitative, objective data for scientific study, for recreation and entertainment or as data points and scoring criteria in contests of osculatory and amatory skill.

One primary advantage of my invention over existing devices is that it is extremely easy to use when compared to another contemporary device cited in the prior art. The users simply approach the device, insert a coin (if it is operating in ‘pay to play’ mode) then each participant places a hand on the appropriate sense plate and the measurement and display commences automatically when they start kissing, without the need for inserting magnetic transducers into the user's mouth or clipping said transducer to the tongue. Ugh! Just the hygienic considerations of such a device used by multiple persons is alarming to a casual observer.

An additional advantage of my invention is that it evaluates a kiss based on multiple parameters, Where previous devices evaluated kissing activity only on the basis of intensity (or physical strength in the case of the Kiss-O-Meter, which is not a ‘kissing test’ at all) my invention calculates and indicates kissing acuity based on both intensity of the kiss and the duration of the kiss. Using my invention a quick ‘peck on the cheek’ may be intense but the limited duration puts it in the ‘Mother-In-Law’ range, a sustained but half-hearted kiss may get to a ‘Platonic’ level and a long, deep kiss with good physical connectivity moves the test subjects up into the “Wowzer” or ‘True Love’ classifications.

### DRAWING FIGURES

I have included three drawings.

FIG. 1 is a general view of the invention with detailed callouts for the unique features.

FIG. 2 is a block diagram of the Processor section of the invention showing the internal configuration of relevant parts used in the invention.

FIG. 3 shows the voltage divider created when human test subjects A and B are inserted in the divider circuit.

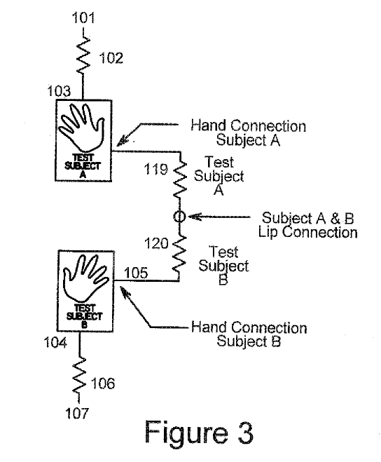

### REFERENCE NUMERALS IN DRAWINGS

101 Sense Loop Voltage Source
102 Sense Loop Current Limiting Resistor
103 Test Subject A Sense Plate
104 Test Subject B Sense Plate
105 Sense Loop Voltage Takeoff Point
106 Building Out Resistor for Sensed Voltage
107 Sense Loop Voltage Return
108 Buffer Amplifier
109 Buffer Output/Processor Input Connection
110 Processor/Microprocessor
111 Indicator Section
112 Processor Operation Modifier Switches
113 Processor Control Program and RAM Memory
114 Processor Analog to Digital Converter Module
115 Processor Timing and Synchronization Modules
116 Processor Control Input/Output Module
117 Processor System Outputs
118 System Bi-Directional Expansion Port
119: Conductive Path through Subject A
120: Conductive Path through Subject B

### DESCRIPTION

A series electrical resistive voltage divider is formed between Sense Loop Voltage Source 101, Sense Loop Current Limiting Resistor 102, Test Subject A Sense Plate 103, Conductive Path through Subject A 119, Conductive Path through Subject B 120, Test Subject B Sense Plate 104, Building Out Resistor for Sensed Voltage 106 and Sense Circuit Voltage Return 107. The scalar voltage values of Sense Loop Voltage Source 101 and Sense Loop Voltage Return 107 are configured such that if there is electrical connectivity of any value between Test Subject A Sense Plate 103 and Test Subject B Sense Plate 104 a current will flow in the divider circuit elements 101 through 107 inclusively.

The value of Sense Loop Current Limiting Resistor 102 is selected to limit maximum current flow through the voltage divider to a level that is safe for human contact, or approximately 1/1000 Ampere. The value of Building Out Resistor for Sensed Voltage 105 is selected to provide a suitable voltage swing through the normal range of galvanic skin response values and was experimentally determined to be approximately one-half Megohm based on multiple field trials.

Test Subject Sense Plate B is electrically connected to the input of a Buffer Amplifier 108 which is characterized by a high input resistance to avoid loading down or ‘swamping’ the input resistive divider network output voltage value and is configured to have an output resistance and voltage range swing compatible with the Analog to Digital input 109 of the Processor/Microprocessor device 110.

The Processor/Microprocessor 110 can be any of a number of general-purpose electronic signal processing devices which have provision for analog and/or digital inputs and outputs, for example almost any of the 16-Series PIC microprocessors from MicroChip Corporation or similar devices with similar specifications. The Processor/Microprocessor 110 includes stored program instructions, random access memory, a variety of input and output nodes and other peripherals depending on the particular part selected. In the case of my invention the internal peripherals of interest are an Analog to Digital Converter, two counter/timer devices and various input and output ports.

The indicator section 111 is driven by (and may be partially incorporated into the) Processor/Microprocessor 110 that can take several configurations as determined by general circuit design and interface requirements with the Processor. There may be an analog meter indicator, a digital numeric output indicator, a ‘thermometer style’ output indicator of a series of Light Emitting Diodes (LEDs), lamps, etc. and/or an audible indication or any combination of these or other indicating devices.

The Processor Operation Modifier Switches section 112 consists of switches or other devices to indicate to the processor the various desired modes of operation as set by the user of the device for its operating parameters.

A bi-directional “KissNet” Expansion Port 118 is included for inter-machine communication.

Not shown in the Figure are various peripherals such as power supplies, etc. which are required for operation but their presence is assumed.

### Operation

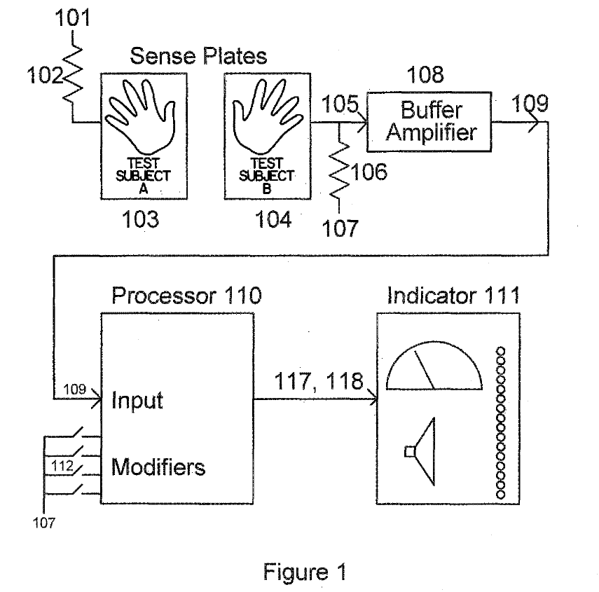

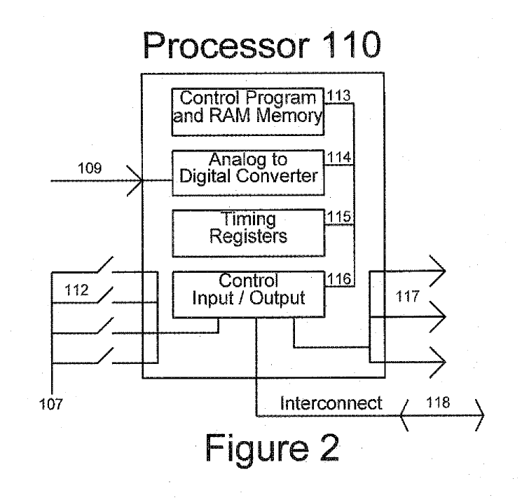

Although the invention may be operated in either the analog, digital or mixed analog/digital domains the following operational description uses the ‘mixed’ model and the operation of the invention is as follows: Referring to FIGS. 1 and 2, users A and B who wish to evaluate their kiss each place one hand on their respective Test Subject Sense Plates A and B 103 and 104. After contacting their hands to the sense plates the participants then engage in kissing activity by connecting lip-to-lip. The physical connection of their lips creates an electrical connection and is now part of the resistive voltage divider 101 through 107, the electrical resistance of which is inversely proportional to the quality of the kissing connection between the participants. Acting under Ohm's Law this kissing connection changes the electrical voltage seen at the input 105 to the Buffer Amplifier 108. The output of the Buffer Amplifier is transferred to the input of the Analog To Digital Converter embedded in the processor device 110.

The Processor 110 is running a program 113 which periodically interrogates the Analog To Digital Converter 114 to determine if a kiss is in progress. If kiss activity is detected the control program initiates a timing sequence via Processor Timing and Synchronization Module registers 115. The A to D output value is instantaneously evaluated and stored in a register and the value is also divided by a fixed number N which is under program control. This result of this division from the A to D value is summed into an accumulator register to aggregate or integrate the kiss quality over N time samples.

While the measurement timing register in block 115 is active the resulting instantaneous and/or aggregate kiss values are transferred to the Output Registers 116 for indicating progress through the Indicator block 111.

During the program sequence the processor may also interrogate the Modifiers switch block 112 through the Control Input/Output register 116. These switches may indicate operational parameters to the program to modify or branch to different routines depending on which switches are activated. For example, one switch may be a coin-operated validation device and the program may require activation of this switch before initiating a timing sequence as described above. Another switch or group of switches may determine how many activations of the aforementioned coin validation device are required to initiate a timing sequence. Yet another switch may indicate multi-mechanism mode is enabled to allow inter-machine kissing competition.

Additionally as a program option the Processor may be configured to correlate instantaneous electrodermal response readings from the test subjects in the time domain to measure and interpolate test subject cardiac rate congruence—another indicator of kiss quality.

The microprocessor program may also incorporate other routines and subroutines to accomplish other tasks within the mechanism, or the routine described previously may be incorporated into the processor program of another device which does other functions as a part of its overall operation. One such routine would be inter-machine communication to coordinate and synchronize multi-couple kissing competitions with a communication path via the Bidirectional Expansion Interface port 118.

### ALTERNATIVE EMBODIMENTS

There are various possibilities for different physical and mechanical arrangements to accomplish the same purpose as described above. For example, other styles or types of microprocessors may be readily substituted. The entire operation could be reconfigured to use only analog components by substituting sample-and-hold circuits for the A to D converter and providing a strictly analog display (D'Arsonval movement or similar) for the output indication.

Although different in form, these alternative configurations would still meet the criteria of the device operation and provide the same user experience.

### CONCLUSION, RAMIFICATIONS, AND SCOPE

Accordingly, the reader will see that the invention provides a novel means for users to evaluate and demonstrate their osculatory prowess or other applications that may become apparent to one skilled in the art.

Although the descriptive information provided above contains many specificities, these should not be construed as limiting the scope of the invention but as merely providing illustrations of some of the presently developed or preferred embodiments of the invention. Mechanical variations in the physical shape or size of the components as well as variations in the software algorithm which could be applied to the operation of the invention are readily imagined and implemented. Thus the scope of the invention should be determined by the appended claims and their legal equivalents rather than by the examples given.

What is claimed is:

1: An apparatus and method for evaluating osculatory kissing skill consisting of an electrical circuit which quantifies the quality of the interpersonal physical engagement of the participants and aggregates that measurement over a period of time resulting in a scalar or vector quantity based on the intensity and duration of the physical engagement of the osculation.

2: The apparatus and method in claim 1 which further provides a visual or auditory or both visual and auditory indication of the measurement.

3: The apparatus and method in claim 1 in which the initiation of the measurement is started or otherwise controlled by the receipt of a coin, token, currency or other thing of value.

4: Multiple instances of the apparatus and method in claim 1 in which the individual instances may interact over a communication pathway to coordinate and synchronize measurement and display of kissing in a competitive or complementary fashion.
